(19) United States
(12) Patent Application Publication
(10) Pub. No.: US 2025/0309211 A1
(43) Pub. Date: Oct. 2, 2025

(54) INTERCONNECT DIE BETWEEN LOGIC DIES STACKED OVER A BASE DIE WITH EMBEDDED MEMORY

(71) Applicant: Intel Corporation, Santa Clara, CA (US)

(72) Inventors: Abhishek A. Sharma, Portland, OR (US); Tahir Ghani, Portland, OR (US); Sagar Suthram, Portland, OR (US); Anand S. Murthy, Portland, OR (US); Wilfred Gomes, Portland, OR (US)

(73) Assignee: Intel Corporation, Santa Clara, CA (US)

(21) Appl. No.: 18/619,617

(22) Filed: Mar. 28, 2024

(51) Int. Cl. H01L 25/18; H01L 23/00; H01L 23/48; H01L 23/538; H10B 80/00

(52) U.S. Cl. CPC H01L 25/18; H01L 23/481; H01L 23/5384; H01L 24/08; H01L 24/09; H10B 80/00; H01L 2224/08145; H01L 2224/08225; H01L 2224/09181; H01L 2924/1431; H01L 2924/1436; H01L 2924/1437

(57) ABSTRACT

Examples of integrated circuit (IC) devices including an interconnect die between logic dies stacked over a base die with embedded memory may enable ultra-high bandwidth memory access. In one example, an IC device includes an interposer (e.g., a die or base die) including embedded memory, a first die (for example, a die including home agent logic) over the interposer, where the first die is hybrid bonded with the interposer. The IC device includes a second die (e.g., a chiplet, compute die, etc.) over the first die. The IC device includes a third die (e.g., an interconnect die) between the first die and the second die, where the third die includes a plurality of interconnect layers and is hybrid bonded with the first die and the second die. In one example, devices in device regions of the first die and second die are coupled via conductive interconnects in the interconnect die.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1D are cross-sectional side views of IC devices including an interconnect die between logic dies stacked over a base die with embedded memory, in accordance with various embodiments.

FIG. 2 illustrates a top-down view of an example IC device that includes an interconnect die between logic dies stacked over a base die with embedded memory, in accordance with any of the embodiments disclosed herein.

FIG. 3 is a cross-sectional view of an example IC device that includes an interconnect die between logic dies stacked over a base die with embedded memory, in accordance with any of the embodiments disclosed herein.

FIG. 4 is a cross-sectional view of an example base die that includes memory, and over which an interconnect die between logic dies may be stacked, in accordance with any of the embodiments disclosed herein.

FIG. 5 illustrates a cross-sectional view of an example memory cell that includes an access transistor and a capacitor, and which may be included in a memory array in a base die, in accordance with any of the embodiments disclosed herein.

FIG. 6 is a schematic illustration of an electric circuit diagram of a 1T-1C memory cell, in accordance with some embodiments of the present disclosure.

FIGS. 7A-7C are cross-sectional views of various examples of an interconnect die, in accordance with any of the embodiments disclosed herein.

FIG. 8 is a block diagram of an example IC device including an interconnect die between logic dies stacked over a base die with embedded memory, in accordance with various embodiments.

FIG. 9 is a block diagram of a home agent, in accordance with any of the embodiments disclosed herein.

FIG. 10 is a block diagram illustrating interconnections in an example IC device including an interconnect die between logic dies stacked over a base die with embedded memory, in accordance with various embodiments.

FIG. 11 is a top view of a wafer and dies that may include any of the IC devices disclosed herein, in accordance with any of the embodiments disclosed herein.

FIG. 12 is a side, cross-sectional view of an IC package that may include any of the IC devices disclosed herein, in accordance with various embodiments.

FIG. 13 is a side, cross-sectional view of an IC device assembly that may include any of the IC devices disclosed herein, in accordance with any of the embodiments disclosed herein.

FIG. 14 is a block diagram of an example electrical device that may include any of the IC devices disclosed herein, in accordance with any of the embodiments disclosed herein.

### DETAILED DESCRIPTION

Disclosed herein are integrated circuit (IC) devices including an interconnect die between stacked dies over a base die with embedded memory, which can enable fast access to embedded memory.

Computing systems commonly include a processor on one die coupled with memory on a separate die, such as a dynamic random-access memory (DRAM), which in addition to being in a separate die, may also be in a separate package. Access to DRAM is typically slow, and therefore processors generally have static random-access memory (SRAM) cache on and/or near the processor die to enable faster data access. Even with large caches and sophisticated caching algorithms, the delay involved in accessing memory remains a significant constraint in achieving faster computational performance.

According to examples described herein, an interconnect die between logic dies stacked over a base die with embedded memory can enable ultra-high bandwidth memory access. In one example, an IC device includes an interposer (e.g., a die or base die) including embedded memory, a first die (for example, a die including home agent logic) over the interposer, where the first die is hybrid bonded with the interposer. The IC device includes a second die (e.g., a chiplet, compute die, processor die, cache die, etc.) over the first die. The IC device includes a third die (e.g., the switch/interconnect die) between the first die and the second die, where the third die includes a plurality of interconnect layers and is hybrid bonded with the first die and the second die. In one example, the interconnect die may also include switches. In one example, devices in device regions of the first die and second die are coupled via conductive interconnects in the interconnect die. In one example, an interconnect die between logic dies stacked over a base die with embedded memory can enable fast and direct access between a compute die stacked over and bonded with the interconnect die and the embedded memory in the base die. For example, the stacked and hybrid bonded configuration in conjunction with the interconnect die can enable higher density/narrower pitch interconnects between a compute die and the embedded memory and/or a higher number of vertical interconnects between the components, which can enable higher bandwidth and faster data transmission. In one example, a home agent die between and hybrid-bonded with the interconnect die and the base die may enable direct and coherent access between a compute die and the embedded memory. In one example, the stacked and hybrid bonded configuration in conjunction with the interconnect die can also enable fast access between chiplets stacked over the interconnect die.

IC devices with an interconnect die between logic dies stacked over a base die with embedded memory as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC(RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC devices with an interconnect die between logic dies stacked over a base die with embedded memory as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

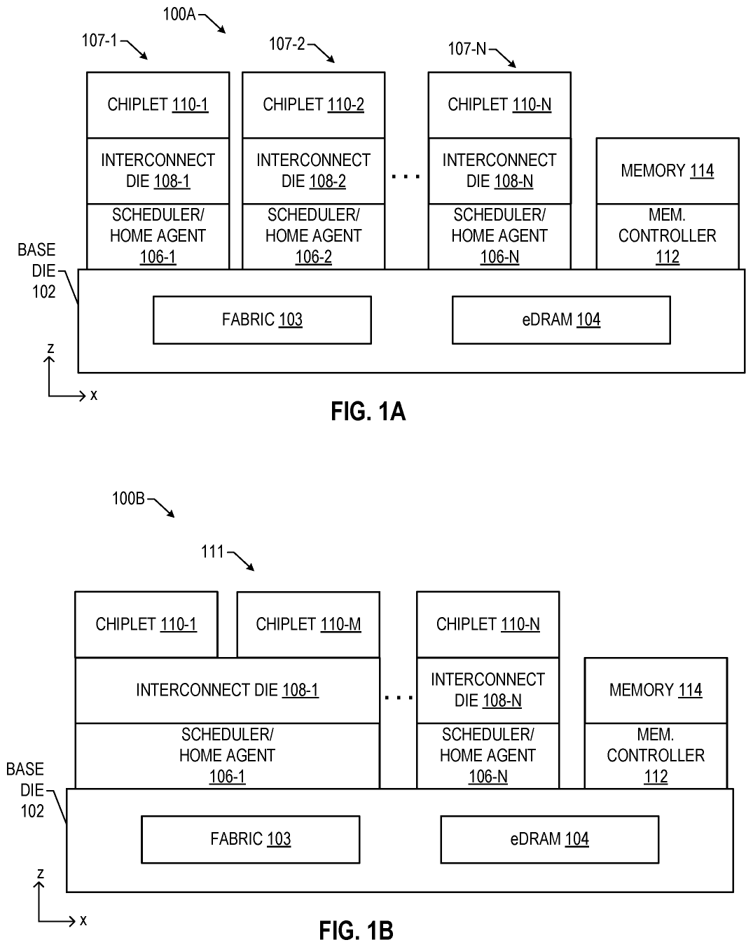

FIGS. 1A-1D are cross-sectional side views of IC devices including an interconnect die between logic dies stacked over a base die with embedded memory, in accordance with various embodiments. FIGS. 1A-1D illustrate various devices that include one or more interconnect dies between other stacked dies over a base die, where the base die includes embedded memory. FIG. 1A illustrates an example IC device 100A including a plurality of die stacks, where a die stack includes an interconnect die between one chiplet and one home agent die. FIG. 1B illustrates an example IC device 100B including an interconnect die with multiple chiplets bonded with the interconnect die. FIG. 1C illustrates an example IC device 100C in which multiple interconnect dies are bonded with one home agent die. FIG. 1D illustrates an example IC device 100D in which multiple chiplets and a memory die are bonded with an interconnect die.

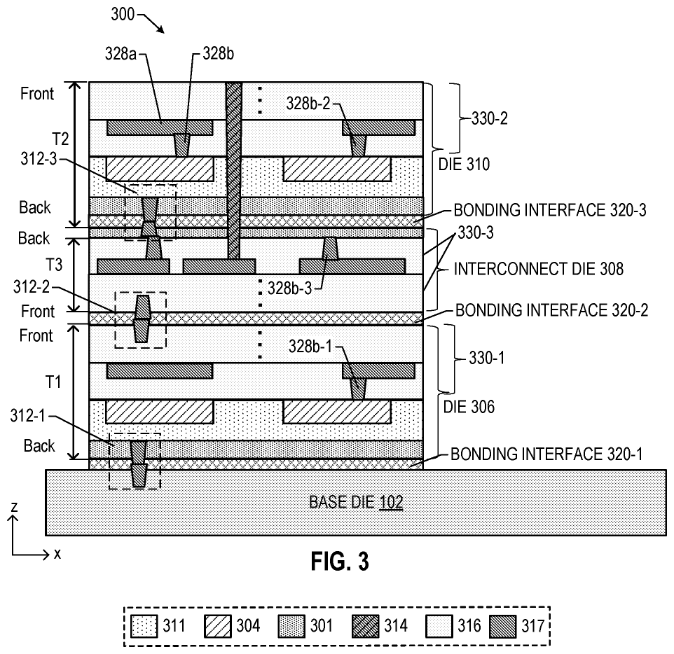

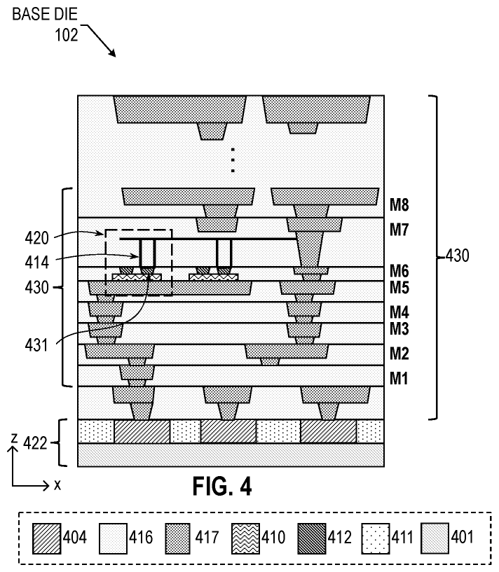

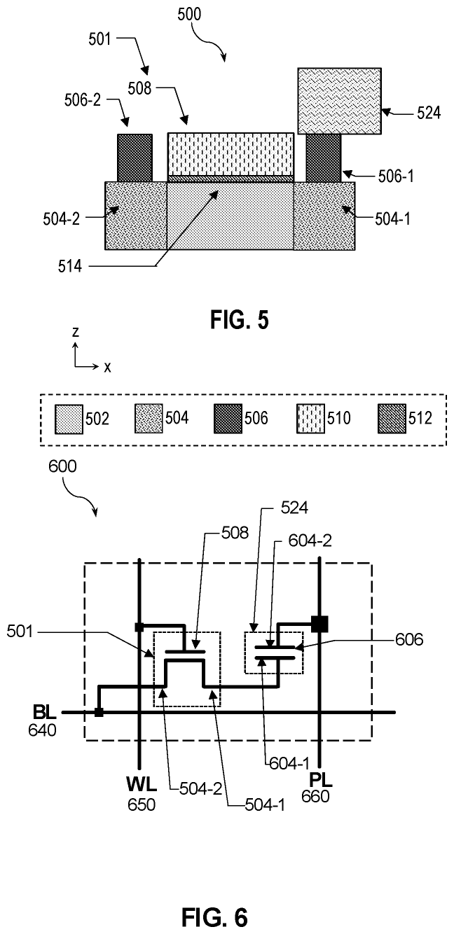

Turning first to FIG. 1A, the IC device 100A includes a base die 102. The base die 102 includes an interconnect fabric 103, which may include a plurality of conductive interconnects. The base die 102 also includes an embedded dynamic random-access memory (eDRAM) 104. The base die 102 may be, for example, an interposer or other IC structure or die over which other dies may be bonded. The fabric 103 may provide conductive paths to electrically and communicatively couple various components on or in the base die 102 to enable the transmission of signals amongst those components. An example of a base die 102 is described in more detail below with respect to FIG. 4. The eDRAM 104 may provide memory resources for one or more processor cores, such as processor cores in one or more chiplets 110-1-110-N over the base die 102. The eDRAM 104 includes an array of memory cells, which may be implemented in the base die 102 according to any suitable DRAM technology. In one example, a memory cell of the eDRAM 104 may include a thin film transistor (TFT) as an access transistor. An example of a TFT-based memory cell is discussed below with respect to FIGS. 5-6. In the example illustrated in FIG. 1A, the IC device 100A also includes a memory die 114 over the base 102. The memory die 114 is external from the base die 102 (e.g., the memory 114 is not embedded in the base die 102), and may provide additional memory resources to the IC device 100A. The memory 114 may include a memory array of any suitable memory technology to add memory capacity to the system. In one such example, the memory 114 includes a high bandwidth memory (HBM) or other DRAM.

In the example illustrated in FIG. 1A, the IC device 100A includes N die stacks 107-1-107-N (of which die stacks 107-1, 107-2, and 107-N are shown), where N is a positive integer greater than or equal to 1. Each of the plurality of die stacks 107-1-107-N of FIG. 1A includes a first die (labeled a scheduler/home agent die in FIG. 1A), a second die (labeled a chiplet in FIG. 1A) over the first die, and a third die (labeled an interconnect die in FIG. 1A) between the first and second dies. For example, the die stack 107-1 includes a home agent die 106-1 over the base die 102, an interconnect die 108-1 over the home agent die 106-1, and a chiplet 110-1 over the interconnect die 108-1. Similarly, the die stack 107-2 includes a home agent die 106-2 over the base die 102, an interconnect die 108-2 over the home agent die 106-2, and a chiplet 110-2 over the interconnect die 108-2, and the die stack 107-N includes a home agent die 106-N over the base die 102, an interconnect die 108-N over the home agent die 106-N, and a chiplet 110-N over the interconnect die 108-N. Thus, in the example of FIG. 1A, there is one chiplet stacked over an interconnect die, and one interconnect die stacked over a home agent die.

A chiplet may be a discrete IC structure or chip, such as a die, which may be packaged with other chiplets. Often, different chiplets in an IC device or system may include logic to provide a particular functionality in the IC device or system. For example, an IC device may include one or more compute chiplets, memory chiplets, cache chiplets, accelerator chiplets, etc. Chiplets may also be referred to as dies; for example, a compute chiplet may also be referred to as a compute die. In one example, a compute chiplet may include one or more processor cores and/or other compute logic. In one example, a compute chiplet that includes one or more processor cores may be referred to as a processor chiplet or processor die. A memory chiplet may include one or more memory arrays (e.g., DRAM or static random-access memory (SRAM) arrays). A cache chiplet may include one or more memory arrays (e.g., an SRAM array or other low latency memory). Chiplets may have more than one type of device, for example, a compute chiplet may also include one or more memory arrays, and a memory chiplet may include compute logic. In one example, the chiplets 110-1-110-N each include one or more processor cores and/or SRAM cache.

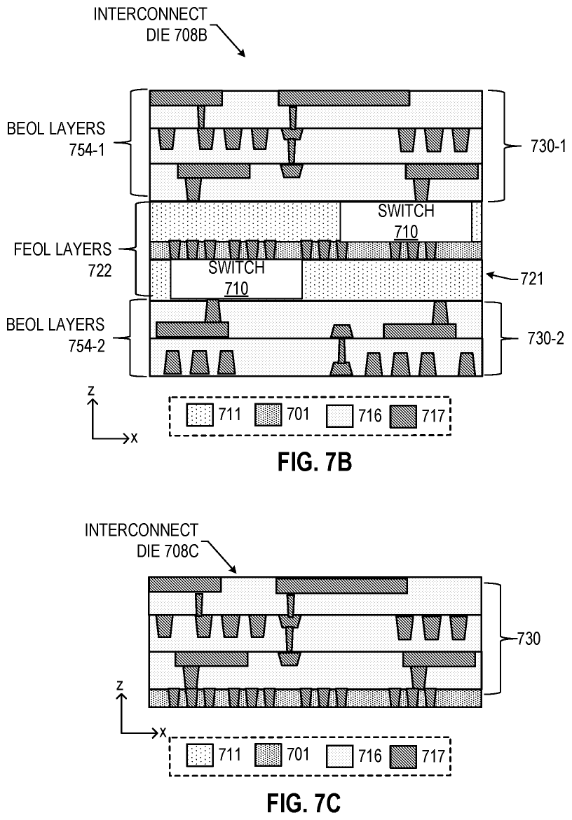

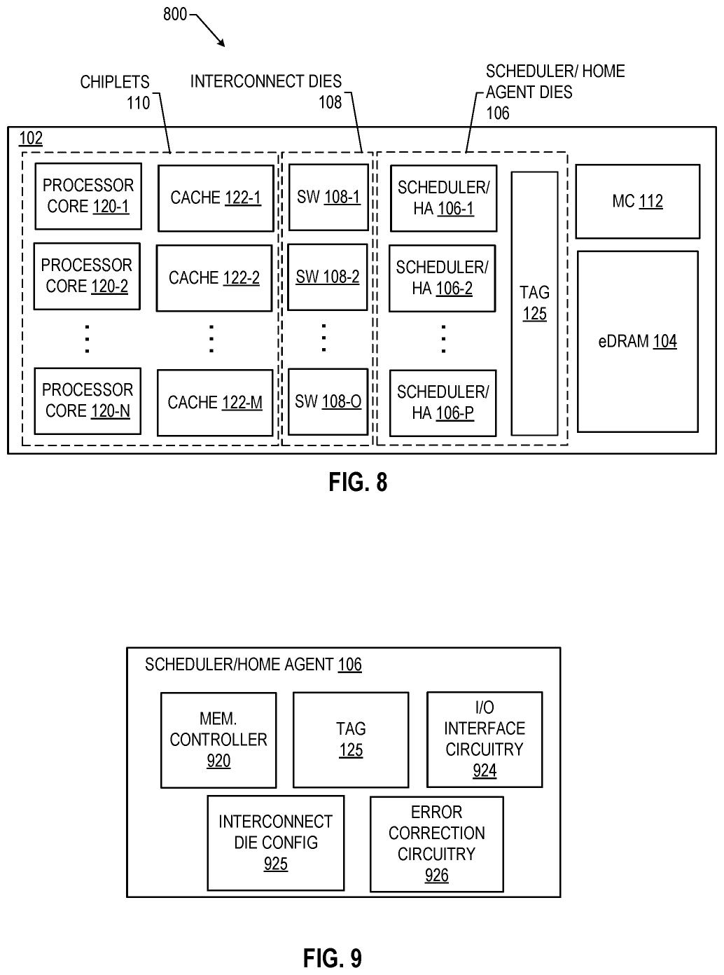

In the example illustrated in FIG. 1A, the chiplets 110-1-110-N are stacked over respective home agent dies 106-1-106-N(of which home agent dies 106-1, 106-2, and 106-N are shown). In one example, the home agent dies 106-1-106-N are logic dies that include logic for performing a variety of functions related to controlling access to the embedded memory 104 and ensuring cache and/or memory coherency in the IC device 100A. In one example, a home agent die includes memory controller circuitry. In one such example, the IC device 100A may include memory controller circuitry in a home agent as well as in a separate die (e.g., as shown with the memory controller 112). In one such example, the home agents 106-1-106-N may be local memory controllers, and the memory controller 112 may be a global memory controller. Examples of memory controllers and home agent dies are discussed below with respect to FIGS. 8-9. Referring again to FIG. 1A, the IC device 100A includes a distributed home agent configuration, in which chiplets 110-1-110-N are stacked over respective home agent dies 106-1-106-N, and home agent functionality for the IC device 100A is distributed amongst the plurality of home agent dies 106-1-106-N.

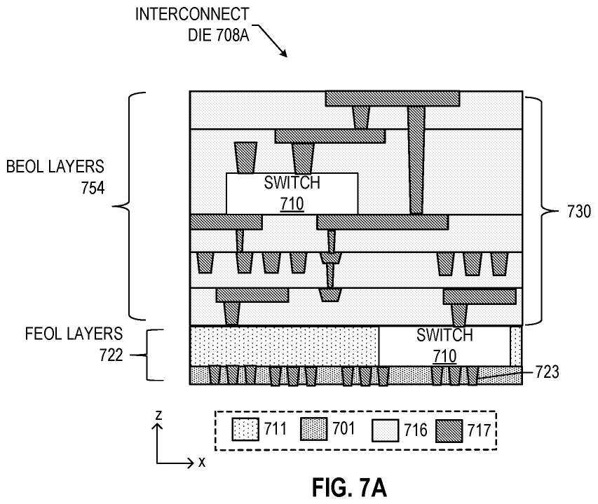

The IC device 100A also includes a plurality of interconnect dies 108-1-108-N(of which interconnect dies 108-1, 108-2, and 108-N are shown) between respective chiplets 110-1-110-N and home agent dies 106-1-106-N. An interconnect die includes a plurality of interconnect layers (e.g., metal layers), where each of the plurality of interconnect layers includes conductive interconnects such as metal lines and/or vias. In some examples, the interconnect dies 108-1-108-N may be passive dies (e.g., dies which have no active transistors). In other examples, the interconnect dies 108-1-108-N may include transistors (e.g., switches to provide configurable routing between components in a die above or below the interconnect die). In one example, an interconnect die includes conductive interconnects that couple a device region of a chiplet with a device region of a respective home agent. Examples of interconnect dies are discussed below with respect to FIGS. 7A-7C.

In one example, the dies of the IC device 100A are bonded together with a hybrid bonding process. For example, the home agent dies 106-1-106-N may be hybrid bonded with the base die, the interconnect dies 108-1-108-N may be hybrid bonded with respective home agent dies 106-1-106-N, and the chiplets 110-1-110-N may be hybrid bonded with respective interconnect dies 108-1-108-N. In one such example, the dies lack separate interconnect structures such as a ball grid array between adjacent dies. In one such example, a bonding interface is present between adjacent dies of the die stacks 107-1-107-N. In one example, hybrid bonding dies including a chiplet, an interconnect die, a home agent die, and a base die with embedded memory enables direct high-speed access between the chiplet and the embedded memory. For example, a stacked and hybrid-bonded configuration such as the configuration shown in FIG. 1A can enable a denser a more direct connection between the chiplet and the embedded memory (e.g., a tighter metal pitch and/or fewer metal lines between the chiplet and the embedded memory) to enable higher bandwidth and/or faster memory access.

FIG. 1B illustrates another example of an IC device 100B including an interconnect die between logic dies stacked over a base die with embedded memory. The IC device 100B differs from the IC device 100A of FIG. 1A in that the IC device 100B includes a die stack 111 that includes multiple chiplets 110-1-110-M (of which chiplets 110-1 and 110-M are shown) over the same interconnect die 108-1, which is stacked over one home agent die 106-1. In one such example, each of the plurality of chiplets 110-1-110-M is hybrid bonded with the interconnect die 108-1. Thus, in the example in FIG. 1B, the home agent logic of the home agent die 106-1 is shared by the chiplets 110-1-110-M.

FIG. 1C illustrates another example of an IC device 100C including an interconnect die between logic dies stacked over a base die with embedded memory. The IC device 100C is similar to the device 100B of FIG. 1B in that the IC device 100C includes a die stack 113 with a plurality of 110-1-110-M over one home agent die 106-1. However, the IC device 100C differs from the IC device 100B in that the chiplets 110-1-110-M are hybrid bonded with respective interconnect dies 108-1-108-M (of which interconnect die 108-1 and 108-M are shown), and the interconnect dies 108-1-108-M are hybrid bonded with the home agent 106-1. Thus, in the example illustrated in FIG. 1C, the home agent die 106-1 is shared by multiple chiplets 110-1-110-M, and the chiplets 110-1-110-M are coupled with he home agent die 106-1 via respective interconnect dies 108-1-108-M.

FIG. 1D illustrates another example of an IC device 100D including an interconnect die between logic dies stacked over a base die with embedded memory. The IC device 100D is similar to the device 100B of FIG. 1B in that the IC device 100D includes a die stack 115 with a plurality of chiplets 110-1-110-M are bonded with the interconnect die 108-1. The IC device 100D differs from the previous examples in that the die stack 115 further includes a memory die 114 stacked over and bonded with the interconnect die 108-1. In the example illustrated in FIG. 1D, the memory controller 112 is included in the base die 102; however, in other examples, a memory controller 112 may be external from the base die, as shown in the prior examples.

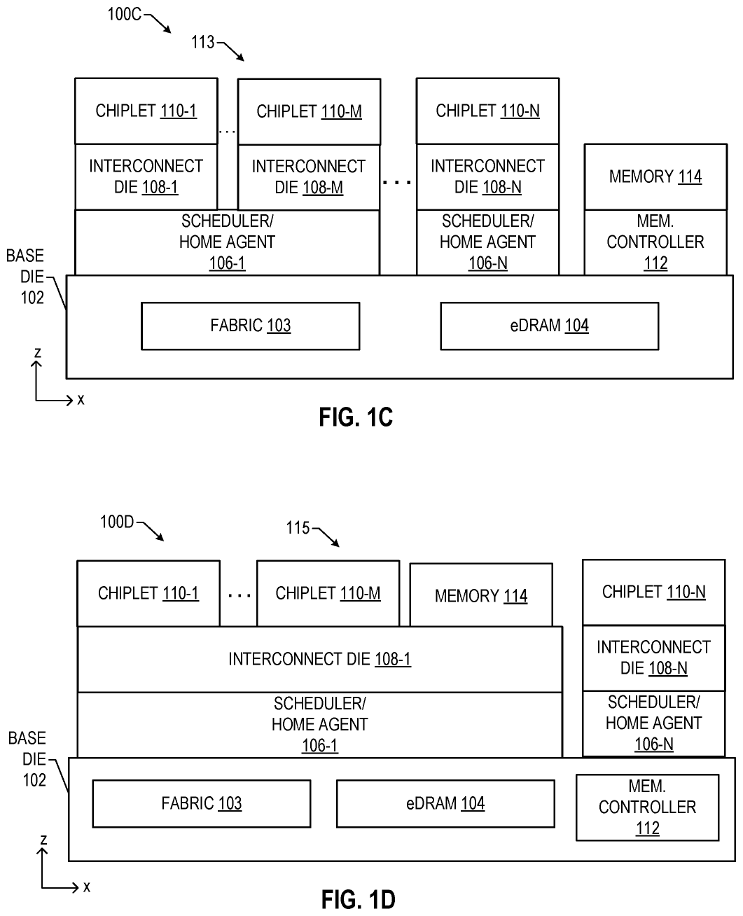

FIG. 2 illustrates a top-down view of an example IC device 200 that includes an interconnect die between logic dies stacked over a base die with embedded memory. The base die 102 is over and coupled with a package substrate or printed circuit board (PCB) 101. The IC device includes a base die 102, a plurality of interconnect dies 108-1, 108-2 over the base die. In one example, home agent dies are present between the interconnect dies 108-1, 108-2, and therefore not visible in the top-down view illustrated in FIG. 2. In the example illustrated in FIG. 2, there are multiple chiplets 110-1-110M and a memory die 114 bonded with the interconnect die 108-1, and multiple chiplets 110-M+1-110-N(of which chiplets 110-M+1 and 110-N are shown) bonded with the interconnect die 108-2. In one example, one or more chiplets may include embedded memory, such as the 117 of the chiplets 110-M+1-110-N).

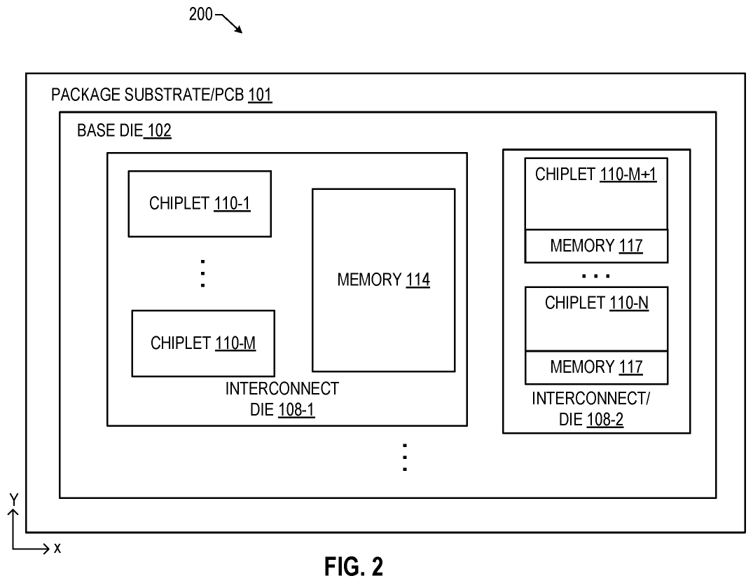

FIG. 3 is a cross-sectional view of an IC device 300 that includes an interconnect die between logic dies stacked over a base die with embedded memory. A number of elements labeled in FIG. 3 and in at least some of the subsequent figures with reference numerals are illustrated in these figures with different patterns, with a legend showing the correspondence between the reference numerals and patterns being provided at the bottom of each drawing page containing these figures. For example, the legend illustrates that FIG. 3 uses different patterns to show a device region 311 and a substrate 301. The IC device 300 may be an example of one of the IC devices 100A, 100B, 100C, or 100D. The IC device 300 includes a base die 102. In one example, the base die 102 may be an interposer or other die or IC structure that includes embedded memory. The IC device 300 includes a first die 306 over the base die 102, where the first die 306 is hybrid bonded with the base die and wherein the first die 306 includes a device region 311 and conductive interconnects 317. The IC device 300 also includes a second die 310 over the first die 306, where the second die 310 includes a device region 311 and conductive interconnects 317. In one example, the dies 306 and 310 include logic transistors, and in some examples may also include memory. In one example, the die 306 may be a home agent and/or scheduler die (e.g., a die that includes home agent and/or scheduler logic), and the die 310 may be a compute die (e.g., a processor die, etc.). In one example, the die 306 is an example of the home agent dies 106 of FIGS. 1A-1D, and the die 310 is an example of a chiplet 110 of FIGS. 1A-1D.

The IC device 300 also includes a third die 308 (e.g., a switch/interconnect die) between the first die 306 and the second die 310, where the third die 308 is hybrid bonded with the first die 306 and the second die 310. The third die 308 includes a plurality of interconnect layers, where the plurality of interconnect layers includes conductive interconnects 317, and the device region 311 of the first die 306 and the device region 311 of the second die 310 are coupled via the conductive interconnects 317 of the interconnect die 308. In the example illustrated in FIG. 3, each of the dies 102, 306, 308, and 310 include a substrate 301. The substrate may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In the dies 306 and 310, the device region 311 is over the substrate 301. In one example, the device regions 311 include frontend devices 304 (e.g., frontend transistors such as FinFETs, nanowire transistors, nanoribbon transistors, frontend memory cells, or other frontend devices). The device regions 311 may also be referred to as front end of line (FEOL) layers.

In one example, the conductive interconnects 317 of the dies 306, 308, and 310 are in interconnect layers over the substrate 301. For example, the die 306 includes interconnect layers 330-1 over a device region 311 and over the substrate 301 of the die 306. The die 308 includes interconnect layers 330-3 over a substrate 301 of the die 308, and the die 310 includes interconnect layers 330-2 over a device region and substrate 301 of the die 310. The interconnect layers may also be referred to as back end of line (BEOL) layers. Each of the interconnect layers 330-1, 330-2, 330-3 include a plurality of interconnects electrically coupled to (e.g., in electrically conductive contact with at least portions of) one or more of devices (e.g., devices in the device regions 311 of the dies 306 or 310). Various interconnect layers 330-1, 330-2, 330-3 may be/include one or more metal layers of a metallization stack of the respective dies 306, 308, 310. Various metal layers of the interconnect layers 330-1, 330-2, 330-3 may be used to interconnect the various inputs and outputs of the devices (e.g., logic devices) in the device regions 311. In one example, each of the interconnect layers 330-1, 330-2, 330-3 may include vias and lines/trenches. For example, a metal layer of the interconnect layers 330-2 includes a via portion 328b and a line or trench/interconnect portion 328a. The trench portion 328a of a metal layer is configured for transferring signals and power along electrically conductive (e.g., metal) lines (also sometimes referred to as “trenches”) extending in the x-y plane (e.g., in the x or y directions), while the via portion 328b of a metal layer is configured for transferring signals and power through electrically conductive vias extending in the z-direction, e.g., to any of the adjacent metal layers above or below. In some examples, the IC device 300 may include one or more inter-die or inter-metal vias, such as the inter-die via 314. In one example, an inter-die via extends through the bonding interface between two dies. For example, as can be seen in FIG. 3, the inter-die via 314 is a via that extends through one or more layers of the die 310 (e.g., an interconnect layer 330-2, the substrate 301, and the device layer 311 of the die 310), through the bonding interface 320-3, and through one or more layers of the die 308 (e.g., the interconnect layers 330-3 of the die 308.

Accordingly, in one example, vias connect metal structures (e.g., metal lines or vias) from one layer to metal structures of an adjacent layer. While referred to as “metal” layers, various layers of the interconnect layers 330-1, 330-2, 330-3 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric ILD 316. The insulating medium may include any suitable ILD materials such as silicon oxide, carbon-doped silicon oxide, silicon carbide, silicon nitride, aluminum oxide, and/or silicon oxynitride. In some embodiments, the dielectric material 316 disposed between the interconnect structures in different ones of the interconnect layers may have different compositions; in other embodiments, the composition of the dielectric material 316 between different interconnect layers may be the same. The example illustrated in FIG. 3 depicts two interconnect layers in each die; however, more than two interconnect layers are generally present, as indicated by the ellipses over the interconnect layers 330-1, 330-2, 330-3.

In one example, the interconnect die 308 is a relatively thin die with fewer layers than the dies 306, 310. For example, the dies 306 and 310 each include a device region 311 and a metallization stack over the device region that may include many metal layers (e.g., 9, 10, 12, or more metal layers). In contrast, the interconnect die 308 may include fewer interconnect layers than the dies 306, 310. In one example, the interconnect die includes six or fewer interconnect layers, or five or fewer interconnect layers. Thus, in one example, the interconnect die 308 may have fewer than half as many interconnect layers as the die 306 or the die 310. The interconnect die may also include a thinner substrate than the dies 306, 310. Thus, the interconnect die 308 may have a smaller thickness than the dies 306, 310. For example, the first die 306 has a height or thickness T1, the second die 310 has a height or thickness T2, and the third die has a height or thickness T3, where the height or thickness of a die is a dimension of the die in a plane that is substantially orthogonal to the base die 102 (e.g., along the z-axis as shown in FIG. 3). In one example, the thickness T3 of the interconnect die 308 is 5-20 times or 5-10 times smaller than the thickness T1 and/or 5-20 times or 5-10 times smaller than the thickness T2.

As mentioned briefly above, adjacent dies in the stack of dies 102, 306, 308, and 310 may be hybrid bonded together.

In hybrid bonding, the bonding process is between a first layer of a first IC structure and a second layer of a second IC structure and also between conductive structures within the first layer and conductive structures within the second layer. For example, in hybrid bonding, conductive structure (e.g., a via including metal) extends through each of the first and second layers, prior to these layers being bonded to form the bonding interface layer. For example, a first interconnect structure extends through the first layer and is exposed through, and flush with, a surface of the first layer; and a second interconnect structure extends through the second layer and is exposed through, and flush with, a surface of the second layer (e.g., prior to the bonding process). During the bonding process, surfaces of the first layer and the second layers bond to form a bonding interface layer, along with a bonding or contact of the first interconnect structure and the second interconnect structure. For example, the IC device 300 includes a combined interconnect structure 312-1 (which may also be referred to simply as an interconnect structure or conductive element) at or through the bonding interface 320-1, where the combined interconnect structure 312-1 includes an interconnect structure in the base die bonded with an interconnect structure in the die 306. Similarly, the IC device 300 includes a combined interconnect structure 312-2 at or through the bonding interface 320-2, where the combined interconnect structure 312-2 is made up of an interconnect structure in the die 306 bonded with an interconnect structure in the die 308. The IC device 300 also includes a combined interconnect structure 312-3 at or through the bonding interface 320-3, where the combined interconnect structure 312-3 is made up of an interconnect structure in the die 308 bonded with an interconnect structure in the die 310. The interconnect structures in adjacent stacked dies that are bonded together may be, for example, conductive vias, conductive pads, or any other suitable conductive elements that may be bonded together via a hybrid bonding process. In one example, due to unintentional practical considerations of the bonding process, the conductive interconnects of the first and second layers may not be perfectly aligned during the bonding process. Accordingly, sections of a combined interconnect structures formed through a hybrid bonding process, which extend through the bonding interface layer, may have some misalignment or offset.

Hybrid bonding may involve bonding a front side of one die to a back side of another die (e.g., “front-to-back”), bonding the back side of one die to the back side of another die (e.g., “back-to-back”), or bonding the front side of one die to the front side of another die (e.g., “front-to-front”). The side of a substrate on which a device layer is provided is typically referred to as a front side, and the other side of the substrate is referred to as a back side. For example, the die 306 includes the device layer 311 over a first side of a substrate 301 and interconnect layers 330-1 as frontside layers at a front side of the die 306, while the opposite side of the substrate 301 of the die 306 is a back side of the substrate. Similarly, the die 308 includes interconnect layers 330-3 over a first side of a substrate 301 of the die 308 as frontside layers at a front side of the die 308, while an opposite side of the substrate 301 of the die 308 is a back side of the die 308. The die 310 includes a device layer 311 over a first side of a substrate 301 and interconnect layers 330-2 as frontside layers at a front side of the die 310, while the opposite side of the substrate 301 of the die 310 is a back side of the substrate. Thus, in the example illustrated in FIG. 3, the die 306 and the base die 102 are hybrid bonded front-to-back, the die 306 and the die 308 are bonded front-to-front, and the die 308 and the die 310 are hybrid bonded back-to-back.

As a result of performing hybrid bonding, bonding interfaces 320-1, 320-2, and 320-3 may be present in the final IC device. In the IC device 300, the bonding interface 320-1 is present between a face (e.g., a front side) of the base die 102 and a face (e.g., a back side) of the die 306 being bonded together, the bonding interface 320-2 is present between a face (e.g., a front side) of the die 306 and a face (e.g., a front side) of the die 308 being bonded together, and the bonding interface 320-3 is present between a face (e.g., a back side) of the die 308 and a face (e.g., a back side) of the die 310 being bonded together.

In some embodiments, hybrid bonding may be performed using insulator-insulator bonding, e.g., as oxide-oxide bonding, where an insulator material of one die is bonded with the insulator material of another die, where the insulator material may be, for example, an insulator material of the substrate 301, an insulator material provided over the back side of the substrate 301 for the purposes of bonding, or an insulator material of the one of the metal layers of the interconnect layers 330-1, 330-2, or 330-3). In some embodiments, a bonding material may be present in between the faces that are bonded together (e.g., one or more of the bonding interfaces 320-1, 320-2, 320-3 may include a bonding material). To that end, the bonding material may be applied to the one or both faces that are to be bonded and then the faces are put together, possibly while applying a suitable pressure and heating up the assembly to a suitable temperature (e.g., to moderately high temperatures, e.g., between about 50 and 200 degrees Celsius) for a duration of time. In some embodiments, the bonding material may be an adhesive material that ensures attachment of the faces of different IC structures to one another. In some embodiments, the bonding material may be an etch-stop material. In some embodiments, the bonding material may be both an etch-stop material and have suitable adhesive properties to ensure attachment of the first and second IC structures to one another. In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using, at a bonding interface, an etch-stop material that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond.

In some embodiments, no bonding material may be used, but there will still be a bonding interface resulting from the hybrid bonding. Such a bonding interface may be recognizable as a seam or a thin layer in the microelectronic assembly, using, e.g., selective area diffraction (SED), even when the specific materials of the insulators of the layers that are bonded together may be the same, in which case the bonding interface would still be noticeable as a seam or a thin layer in what otherwise appears as a bulk insulator (e.g., bulk oxide) layer.

Thus, in one example, the IC device 300 includes a first bonding interface 320-1 between the first die 306 and the base die 102, a second bonding interface 320-2 between the first die 306 and the interconnect die 308, and a third bonding interface 320-3 between the interconnect die 308 and the second die 310. In one example, the bonding interfaces 320-1, 320-2, 320-3 may include interface layers that include one or more of silicon, nitrogen, oxygen, and carbon.

Depending on the orientation of the hybrid bonded dies (e.g., whether the dies are bonded back-to-back, front-to-back, etc.), conductive vias in the dies 102, 306, 308, 310 may have shapes that taper in particular directions in the final IC device. For example, in the example illustrated in FIG. 3, the interconnect die 308 is “flipped over” relative to the dies 306 and 310, resulting in the vias of the interconnect die to taper in an opposite direction relative to the vias in the dies 306 and 310. For example, the first die 306 includes a first backend via 328b-1, the second die 310 includes a second backend via, and the third die 308 includes a third backend via 328b-3. In one example, in a cross-section of the IC device 300 in a plane substantially perpendicular to the substrate 301 of one of the dies (or perpendicular to the device region 311 of one of the dies), the first backend via 328b-1 and the second backend via 328b-2 have shapes that taper in a direction from the respective backend via towards the base die 102, and the third backend via 328b-3 has a shape that tapers in a direction from the third backend via 328b-3 away from the base die 102. In one example (not shown in FIG. 3), the interconnect die 308 may further include one or more backside interconnect layers, including a backside via. For example, FIG. 7C, which is discussed below, shows an example of an interconnect die with interconnect layers over both a front side and a back side of a substrate. In one such example, in a cross-section of the IC device in a plane substantially perpendicular to the substrate, the backside via has a shape that tapers in the opposite direction relative to the backend via of the interconnect die (e.g., the backside via may taper in a direction from the backside via towards the base die).

FIG. 4 is a cross-sectional view of an example base die 102 that includes memory, and over which an interconnect die between logic dies may be stacked. The base die 102 includes FEOL layers 422, which includes a substrate 401, and which may also include a device region 411. The substrate 401 may be a semiconductor substrate, and may be an example of the substrate 301 discussed above. The device region 411 may include frontend devices 404, such as transistors for forming memory control logic, switching logic, etc., and/or memory devices. The base die 102 includes a metallization stack including plurality of interconnect layers 430 over the device region 411. In the example illustrated in FIG. 4, the plurality of interconnect layers 430 include metal layers labeled as metal layer 1 (M1), metal layer 2 (M2), and so on. The interconnect layers 430 include an ILD 416 and conductive interconnects 417, such as the conductive lines and vias discussed above with respect to FIG. 3.

In the example illustrated in FIG. 4, the base die 102 includes backend memory devices in one or more of the interconnect layers 430 (e.g., backend memory devices are located in metal layers M5, M6, and M7 in FIG. 4). For example, FIG. 4 illustrates access transistors 410, source and drain (S/D) contacts 412 for the access transistors 410, and capacitors 414. FIG. 4 further provides a label for a memory cell 420, illustrated in FIG. 4 within a dashed rectangular contour, that includes one access transistor 410 and one capacitor 414, coupled to one of the S/D contacts 412 of the access transistor 410. Thus, the memory cell 420 is an example of a one transistor and one capacitor (1T-1C) memory cell. In the example illustrated in FIG. 4, the access transistor 410 is a backend transistor and the memory cell 420 is a backend memory cell. Two such memory cells 420 are shown in FIG. 4, but only one is labeled with reference numerals in order to not clutter the drawing. The memory cell 420 may be a backend memory cell according to any suitable memory architecture. For example, as shown in FIG. 4, in some embodiments of the memory cell 420, one of the interconnects 417 in a metal layer M5 may form a control or access line such as a wordline, while the access transistor 410, a storage node such as the storage node 431, and another access or control line, such as a bitline, may be formed in a metal layer M6 of the interconnect layers 430. In one such example, the capacitor 414 may then be formed in a metal layer M7. In one example, a further access or control line, such as a plate line, may be coupled to one of the interconnects in the metal layer M7. In other examples, memory cells and access or control lines for accessing the memory cells may be implemented in other BEOL layers other than, or in addition to, metal layers M5-M7. Additionally, any number of memory cells 420 may be included in a given layer/array of backend memory cells, and multiple layers of backend memory cells such as the memory cell 420 may be stacked over one another, thus implementing three-dimensional (3D) stacked backend memory.

FIG. 5 illustrates a cross-sectional view of an example memory cell 500 that includes an access transistor and a capacitor, and which may be included in a memory array in the base die 102. The memory cell 500 may be an example of the memory cell 420 of FIG. 4. The memory cell 500 includes an access transistor 501 coupled with a capacitor 524. The access transistor 501 may be a FET, e.g., a metal oxide semiconductor (MOS) FET (MOSFET), which includes a channel material 502, S/D regions 504 (shown as a first S/D region 504-1, e.g., a source region, and a second S/D region 504-2, e.g., a drain region), contacts 506 to S/D regions (shown as a first S/D contact 506-1, providing electrical contact to the first S/D region 504-1, and a second S/D contact 506-2, providing electrical contact to the second S/D region 504-2), and a gate stack 508, which includes at least a gate electrode 510 and may also, optionally, include a gate dielectric 512.

In some embodiments, the channel material 502 may be composed of semiconductor material systems including, for example, N-type or P-type materials systems. In some embodiments, the channel material 502 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 502 may include a combination of semiconductor materials where one semiconductor material may be used for the channel portion (e.g., a portion 514 shown in FIG. 5, which is supposed to refer to the upper-most portion of the channel material 502) and another material, sometimes referred to as a “blocking material,” may be used between the channel portion 514 and the support structure over which the transistor 501 is provided. In some embodiments, the channel material 502 may include a monocrystalline semiconductor, such as silicon (Si) or germanium (Ge). In some embodiments, the channel material 502 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 501 is an NMOS), the channel portion 514 of the channel material 502 may advantageously include a III-V material having a high electron mobility, such as, but not limited to InGaAs, InP, InSb, and InAs. For some such embodiments, the channel portion 514 of the channel material 502 may be a ternary III—V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel portion 514 of the channel material 502 may be an intrinsic III-V material, i.e., a III-V semiconductor material not intentionally doped with any electrically active impurity. In alternate embodiments, a nominal impurity dopant level may be present within the channel portion 514 of the channel material 502, for example to further fine-tune a threshold voltage Vt, or to provide HALO pocket implants, etc. Even for impurity-doped embodiments however, impurity dopant level within the channel portion 514 of the channel material 502 may be relatively low, for example below 10¹⁵ dopant atoms per cubic centimeter (cm⁻³), and advantageously below 10¹³ cm⁻³.

For some example P-type transistor embodiments (i.e., for the embodiments where the transistor 501 is a PMOS), the channel portion 514 of the channel material 502 may advantageously be a group IV material having a high hole mobility, such as, but not limited to Ge or a Ge-rich SiGe alloy. For some example embodiments, the channel portion 514 of the channel material 502 may have a Ge content between 0.6 and 0.9, and advantageously may be at least 0.7. In some embodiments with highest mobility, the channel portion 514 may be intrinsic III-V (or IV for P-type devices) material and not intentionally doped with any electrically active impurity. In alternate embodiments, one or more a nominal impurity dopant level may be present within the channel portion 514, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³.

In some embodiments, the transistor 501 may be a thin film transistor (TFT). A TFT is a special kind of a field-effect transistor made by depositing a thin film of an active semiconductor material, as well as a dielectric layer and metallic contacts, over a supporting layer that may be a non-conducting layer. At least a portion of the active semiconductor material forms a channel of the TFT. If the transistor 501 is a TFT, the channel material 502 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor 501 is a TFT, the channel material 502 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material 502 may have a thickness between about 5 and 75 nanometers, including all values and ranges therein. In some embodiments, a thin film channel material 502 may be deposited at relatively low temperatures, which allows depositing the channel material 502 within the thermal budgets imposed on back end fabrication to avoid damaging other components, e.g., front end components such as the logic devices. Although some examples herein refer to memory cells with TFTs for access transistors, the memory included in a base die may include memory array of any suitable memory technology. For example, memory cells may include access transistors of any suitable architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field.

Referring again to FIG. 5, a first and a second S/D regions 504-1, 504-2 (together referred to as “S/D regions 504”) may be included on either side of the gate stack 508, thus realizing a transistor 501. As is known in the art, source and drain regions (also sometimes interchangeably referred to as “diffusion regions”) are formed for the gate stack of a FET. In some embodiments, the S/D regions 504 of the transistor 501 may be regions of doped semiconductors, e.g. regions of the channel material 502 (e.g., of the channel portion 514) doped with a suitable dopant to a desired dopant concentration, so as to supply charge carriers for the transistor channel. In some embodiments, the S/D regions 504 may be highly doped, e.g. with dopant concentrations of about 1·10²¹ cm⁻³, in order to advantageously form Ohmic contacts with the respective S/D contacts 506, although, in other embodiments, these regions may also have lower dopant concentrations and may form Schottky contacts in some implementations. Irrespective of the exact doping levels, the S/D regions 504 of the transistor 501 may be the regions having dopant concentration higher than in other regions, e.g. higher than a dopant concentration in a region of the channel material 502 between the first S/D region 504-1 and the second S/D region 504-2, and, therefore, may be referred to as “highly doped” (HD) regions. In some embodiments, the S/D regions 504 may generally be formed using either an implantation/diffusion process or an etching/deposition process. In the former process, dopants such as boron, aluminum, antimony, phosphorous, or arsenic may be ion-implanted into the one or more semiconductor materials of the upper portion of the channel material 502 to form the S/D regions 504. An annealing process that activates the dopants and causes them to diffuse further into the channel material 502 may follow the ion implantation process. In the latter process, the one or more semiconductor materials of the channel material 502 may first be etched to form recesses at the locations for the future S/D regions. An epitaxial deposition process may then be carried out to fill the recesses with material (which may include a combination of different materials) that is used to fabricate the S/D regions 504. In some implementations, the S/D regions 504 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 504 may be formed using one or more alternate semiconductor materials such as germanium or a group III-V material or alloy. Although FIG. 5 illustrates the first and second S/D regions 504 with a single pattern, suggesting that the material composition of the first and second S/D regions 504 is the same, this may not be the case in some other embodiments of the transistor 501. Thus, in some embodiments, the material composition of the first S/D region 504-1 may be different from the material composition of the second S/D region 504-2.

As further shown in FIG. 5, S/D contacts 506-1 and 506-2 (together referred to as “S/D contacts 506”), formed of one or more electrically conductive materials, may be used for providing electrical connectivity to the S/D regions 504-1 and 504-2, respectively. In various embodiments, one or more layers of metal and/or metal alloys may be used to form the S/D contacts 506. For example, the electrically conductive materials of the S/D contacts 506 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the S/D contacts 506 may include one or more electrically conductive alloys, oxides, or carbides of one or more metals. In some embodiments, the S/D contacts 506 may include a doped semiconductor, such as silicon or another semiconductor doped with an N-type dopant or a P-type dopant. Metals may provide higher conductivity, while doped semiconductors may be easier to pattern during fabrication. Although FIG. 5 illustrates the first and second S/D contacts 506 with a single pattern, suggesting that the material composition of the first and second S/D contacts 506 is the same, this may not be the case in some other embodiments of the transistor 501. Thus, in some embodiments, the material composition of the first S/D contact 506-1 may be different from the material composition of the second S/D contact 506-2.

Turning to the gate stack 508, the gate electrode 510 may include at least one P-type work function metal or N-type work function metal, depending on whether the transistor 501 is a P-type metal oxide semiconductor (PMOS) transistor or an N-type metal oxide semiconductor (NMOS) transistor. For a PMOS transistor, metals that may be used for the gate electrode 510 may include, but are not limited to, ruthenium, palladium, platinum, cobalt, nickel, and conductive metal oxides (e.g., ruthenium oxide). For an NMOS transistor, metals that may be used for the gate electrode 510 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 510 may include a stack of two or more metal layers, where one or more metal layers are work function (WF) metal layers and at least one metal layer is a fill metal layer.

If used, the gate dielectric 512 may at least laterally surround the channel portion 514, and the gate electrode 510 may laterally surround the gate dielectric 512 such that the gate dielectric 512 is disposed between the gate electrode 510 and the channel material 514. In various embodiments, the gate dielectric 512 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 512 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 512 during manufacture of the transistor 501 to improve the quality of the gate dielectric 512. In some embodiments, the gate dielectric 512 may have a thickness between about 0.5 nanometers and 3 nanometers, including all values and ranges therein, e.g., between about 1 and 3 nanometers, or between about 1 and 2 nanometers.

In some embodiments, the gate dielectric 512 may be a multilayer gate dielectric, e.g., it may include any of the high-k dielectric materials in one layer and a layer of indium gallium zinc oxide (IGZO). In some embodiments, the gate stack 508 may be arranged so that the IGZO is disposed between the high-k dielectric and the channel material 514. In such embodiments, the IGZO may be in contact with the channel material 514 and may provide the interface between the channel material 514 and the remainder of the multilayer gate dielectric 512. The IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10).

In some embodiments, the gate stack 508 may be surrounded by a dielectric spacer, not specifically shown in FIG. 5. The dielectric spacer may be configured to provide separation between the gate stacks 508 of different transistors 501 which may be provided adjacent to one another, as well as between the gate stack 508 and one of the S/D contacts 506 that is disposed on the same side as the gate stack 508. Such a dielectric spacer may include one or more low-k dielectric materials. Examples of the low-k dielectric materials that may be used as the dielectric spacer include, but are not limited to, silicon dioxide, carbon-doped oxide, silicon nitride, fused silica glass (FSG), and organosilicates such as silsesquioxane, siloxane, and organosilicate glass. Other examples of low-k dielectric materials that may be used as the dielectric spacer include organic polymers such as polyimide, polynorbornenes, benzocyclobutene, perfluorocyclobutane, or polytetrafluoroethylene (PTFE). Still other examples of low-k dielectric materials that may be used as the dielectric spacer include silicon-based polymeric dielectrics such as hydrogen silsesquioxane (HSQ) and methylsilsesquioxane (MSQ). Other examples of low-k materials that may be used in a dielectric spacer include various porous dielectric materials, such as for example porous silicon dioxide or porous carbon-doped silicon dioxide, where large voids or pores are created in a dielectric in order to reduce the overall dielectric constant of the layer, since voids can have a dielectric constant of nearly 1.

in some embodiments, a capacitor 524 may be coupled to the S/D contact 506-1 of the transistor 501. The capacitor 524 may be any suitable capacitor, e.g., a metal-insulator-metal (MIM) capacitor for storing a bit value, or a memory state (e.g., logical “1” or “0”) of the memory cell 500, and the transistor 501 may then function as an access transistor controlling access to the memory cell 500 (e.g., access to write information to the cell or access to read information from the cell). By coupling one electrode of the capacitor 524 to the S/D region 504-1, the capacitor 524 is configured to store the memory state of the memory cell 500. In some embodiments, the capacitor 524 may be coupled to the S/D region 504-1 via a storage node (not specifically shown in FIG. 5) coupled to the S/D region 504-1. In some embodiments, the S/D contact 506-1 may be considered to be the storage node.

Although not specifically shown in FIG. 5, the memory cell 500 may further be coupled with a bitline to transfer the memory state and coupled to the one of the S/D regions 504 to which the capacitor 524 is not coupled (e.g., to the S/D region 504-2, via the S/D contacts 506-2, for the illustration of FIG. 5). Such a bitline can be connected to a sense amplifier and a bitline driver which may, e.g., be provided in a memory peripheral circuit associated with a memory array in which the memory cell 500 may be included. In one such example, such a memory peripheral circuit may be implemented with frontend devices (such as the devices 404 of FIG. 4). Furthermore, although also not specifically shown in FIG. 5, a wordline may be coupled to the gate terminal of the transistor 501, e.g., coupled to the gate stack 508, to supply a gate signal. The transistor 501 may be configured to control transfer of a memory state of the memory cell 500 between the bitline and the storage node or the capacitor 524 in response to the gate signal.

FIG. 6 is a schematic illustration of an electric circuit diagram of a 1T-1C memory cell 600 according to some embodiments of the present disclosure. The memory cell 600 is an example of the memory cell 500, shown in FIG. 5, but illustrating a different representation. Similar to FIG. 5, FIG. 6 illustrates how the transistor 501 and the capacitor 524 may be used to form a 1T-1C memory cell. In particular, the memory cell 600 illustrates the S/D regions 504 and the gate stack 508 of the transistor 501 of FIG. 5 and further illustrates the capacitor 524 coupled to one of the S/D regions 504 of the transistor 501, where the capacitor 524 is shown to include a first capacitor electrode 604-1 and a second capacitor electrode 604-2, and an insulator material 606 between the first and second capacitor electrodes 604. In addition to what was shown in FIG. 5 and described above, the FIG. 6 illustrates a bitline 640 (labeled in FIG. 6 as “BL”), a wordline 650 (labeled in FIG. 6 as “WL”) and a plateline 660 (labeled in FIG. 6 as “PL”). Each of the bitline 640, the wordline 650, and the plateline 660, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as copper, ruthenium, palladium, platinum, cobalt, nickel, hafnium, zirconium, titanium, tantalum, aluminum, tantalum nitride, tungsten, doped silicon, doped germanium, or alloys and mixtures of any of these. In some embodiments, such electrically conductive materials may include one or more electrically conductive alloys oxides or carbides of one or more metals.

As shown in FIG. 6, in the 1T-1C memory cell 600, the gate terminal (e.g., the gate stack 508) of the access transistor 501 is coupled to the wordline 650, the first S/D terminal (e.g., the first S/D region 504-1) is coupled to the capacitor 524, and the second S/D terminal (e.g., the second S/D region 504-2) is coupled to the bitline 640. In particular, the first S/D region 504-1 is coupled to the first capacitor electrode 604-1, while the second capacitor electrode 604-2 is coupled to the plateline 660. As is known in the art, the wordlines, bitlines, and platelines may be used together to read and program the capacitor 524.

FIGS. 7A-7C are cross-sectional views of various examples of an interconnect die. As mentioned above, an interconnect die may include a relatively thin die with interconnect layers over a thin substrate. In some examples, an interconnect die may include switches in addition to passive conductive interconnects. An interconnect die may also be referred to as a switch die, or simply as a die or IC structure. FIG. 7A illustrates an example interconnect die 708A that includes a plurality of interconnect layers 730 that include an ILD 716 and conductive interconnects 717, and also switches 710 coupled with conductive interconnects 717. FIG. 7B illustrates another example of an interconnect die 708B that includes switches 710 over both a front side and back side of a substrate as well as interconnect layers 730-1, 730-2 over the front and back side of a substrate. FIG. 7C illustrates an example of a passive interconnect die 708C without switches.

Turning first to FIG. 7A, the interconnect die 708A includes FEOL layers 722 and BEOL layers 754 over the FEOL layers 722. In one example, the FEOL layers 722 include a device layer 711 over a substrate 701. The device layer 711 may include one or more device layers including frontend devices. The substrate 701 may be a substrate in accordance with the example substrates discussed above. In one example, the substrate 701 may be thinned (e.g., polished, etched, or otherwise removed) to the point that conductive elements 723 in the substrate and/or device layer 711 may be exposed at a backside of the interconnect die 708A. The conductive elements 723 in the substrate 701 exposed at the backside of the substrate 701 may then make contact with and be bonded with conductive elements of another die (e.g., a logic die, a home agent die, etc.). In one example, the conductive elements may include, for example, conductive vias (e.g., through-silicon vias (TSVs)), conductive pads, or other conductive interconnects. In one example, the conductive elements are terminals of switches 710 in the device layer 711, or are coupled with terminals of switches 710 in the device layer 711. In one example, the conductive elements 723 are to be hybrid bonded with conductive elements of another die, and therefore the conductive elements 723 have a relatively narrow pitch (e.g., compared to the pitch of conductive elements to be coupled with a ball grid array (BGA)). For example, the conductive elements may have a pitch of less than 5 microns, or in a range of 500 nanometers to 5 microns, or 700 nanometers to 4 microns.

In the example illustrated in FIG. 7A, the interconnect die 708A includes a switch 710 in a FEOL layer 722 and a switch 710 in a BEOL 754. In one such example, the switch 710 in the FEOL layer 722 is or includes a frontend transistor, and the switch 710 in the BEOL layer 754 is or includes a backend transistor. In one example, any suitable transistor architecture may be used to implement the switches 710. In some examples, the interconnect die 708A may include only frontend switches, only backend switches, or a combination of frontend and backend switches. The switches may be programmed (e.g., by circuitry in another die, such as a home agent die) to configure how the interconnects in the interconnect layers 730 couple with other conductive interconnects of dies that are hybrid bonded on either side of the interconnect die 708A. Thus, in one example, the interconnect die 708A may include a network of configurable switches 710 to enable different configurations of interconnections amongst dies that are bonded with the interconnect die 700A.

FIG. 7B illustrates another example of an interconnect die 708B that includes backside layers 721 over a backside of the substrate 701. In the example illustrated in FIG. 7B, the backside layers 721 include both a device layer 711 with switches 710 and interconnect layers 730-2, so that the substrate 701 is between two device layers 711 with switches 710 and between two stacks of interconnect layers 730-1, 730-2. In other examples, the interconnect die 708B may include switches 710 in only one of the device layers 711 (e.g., switches 710 only over the front side of the substrate 701 or only over the back side of the substrate 701). Thus, the interconnect die 708B of FIG. 7B includes both frontside and backside metal layers (e.g., BEOL layers 754-1 and BEOL layers 754-2). In one such example, the frontside and backside metal layers include conductive vias that taper in opposite directions (e.g., vias in the interconnect layers 730-1 and the vias in the interconnect layers 730-2 both taper in a direction towards the substrate 701 that is in between the interconnect layers 730-1 and 730-2). The interconnect layers 730-1 and 730-2 may include the same number of layers or a different number of interconnect layers. Also, an interconnect die 708B may be a passive interconnect die with frontside and backside interconnect layers, but without the switches 710.

FIG. 7C illustrates another example of an interconnect die 700C without switches 710 (e.g., a passive interconnect die). In the example illustrated in FIG. 7C, the interconnect layers 730 are directly over the substrate 701 without an intervening device layer (e.g., one of the interconnect layers 730 is in directly contact with the substrate 701). In one example, the interconnect die 708C lacks a device region and lacks transistors. For example, transistors are absent from a layer directly over the substrate 701 and also absent from the BEOL layers. Thus, the interconnect die 708C can be referred to as a passive interconnect die. As mentioned above with respect to FIG. 7B, a passive interconnect die may also include backside interconnect layers (such as the layers 730-2), so that there are interconnect layers on both sides of the substrate 701.

FIG. 8 is a block diagram of an example IC device 800 including an interconnect die between logic dies stacked over a base die with embedded memory. FIG. 8 depicts that an IC device 800 may include various numbers of chiplets 110, interconnect dies 108, home agent dies 106 over a base die 102 with embedded DRAM 104, and may further include other logic such as a memory controller 112, which may be included in the IC device 800 as a discrete die over the base die 102, embedded in the base die 102, or disaggregated across multiple locations of the IC device 800. On a given base die 102, there may be one or a plurality of chiplets 110. In one example, a chiplet 110 may be a dedicated processor core die without cache, a dedicated cache die without a processor core, or a die with both a processor core and cache. In one example, an IC device may include a variety of different chiplets (e.g., one chiplet that includes a processor core and cache, and a separate cache-only chiplet, etc.). In one example, the IC device includes N processor cores 120-1-120N (of which processor cores 120-1, 120-2, and 120-N are shown) and M caches 122-1-122-M (of which caches 122-1, 122-2, and 122-M are shown), which may be located on separate dies, combined dies, or a combination of separate and combined dies. Although not shown in FIG. 8, chiplets may also, or alternatively, include dies that include other functionality, such as one or more DRAM dies, accelerator dies, or other dies.

The chiplets 110 may be stacked over and bonded with interconnect dies 108, as shown in FIGS. 1A-1D. In the example illustrated in FIG. 8, the IC device 800 includes O interconnect dies 108-1-108-O (of which 108-1, 108-2, and 108-O are shown. The interconnect dies 108 may be stacked over and bonded with home agent dies 106. In the example illustrated in FIG. 8, the IC device 800 includes P home agent dies 106-1-106-P (of which home agent dies 106-1, 106-2, and 106-P are shown). In FIG. 8, N, M, O, and P are positive integers (e.g., integers that are greater than or equal to 1), and may have the same values or different values. For example, one or more processor cores 120-1-120-N and/or cache 122-1-122-M may be included on a chiplet 110, one or more chiplets 110 may be stacked over and bonded with an interconnect die, one or more interconnect dies may be stacked over and bonded with a home agent die 106, and one or more home agent dies 106 may be stacked over and bonded with the base die 102. Additionally, a system may include one or more IC devices 800.

In the example illustrated in FIG. 8, the IC device 800 is shown as including a tag array 125, which may be a structure that stores address information (e.g., address tag bits, pointers, or other location information) and other data such as valid or dirty bits to enable a requester to determine the presence and validity of target data in a cache and/or memory based on the memory address of the target data. The tag array 125 may be implemented with, for example, an SRAM or another storage array that enables fast access to the tag information. In one example, the tag array 125 may be physically located in one home agent die 106, disaggregated across multiple home agent dies 106, or located in another die, such as one or more of the processor cores 120-1-120-N. In one example, the tag array 125 may be a common or shared tag array for a plurality of caches 122-1-122-M associated with a plurality of processor cores 120-1-120N. In one example, the tag array 125 may map or track what data is located in the caches ‘122-1-122-M, but may also map or track what data is located in the eDRAM 104. In one such example, a shared tag array 125 in the stacked and hybrid bonded configurations described herein can enable fast cache and memory access.

FIG. 9 is a block diagram of an example home agent 106. In the example illustrated in FIG. 9, the home agent die 106 includes a memory controller 920, a tag array 125, input/output (I/O) interface circuitry 924, and error correction circuitry 926. In one example, the memory controller 920 may be a local memory controller (e.g., local for a memory domain of the embedded memory 104 associated with one or more processor cores stacked over the home agent 106). In one such example, the IC device or system that includes the home agent may have another memory controller (such as the memory controller 112 of FIG. 8), which may be a global memory controller. In one such example, a local memory controller may control access to memory locations in a domain, and a global memory controller may route access request to local memory controllers to enable access of memory locations in other domains.

In one example, the memory controller 920 includes control logic to generate and issue commands to memory (e.g., to the eDRAM 104). The memory controller 920 may include scheduling logic to schedule commands to the eDRAM 104 and/or to chiplets coupled with the home agent 106. In other examples, scheduling logic may be separate from the home agent 106. The memory controller 920 may also include coherency logic to ensure coherency of data in the caches 122-1-122-M and embedded DRAM 104. In one such example the home agent 106 may be a cache home agent or caching home agent (CHA) to enable local and/or global coherence (e.g., local coherence of a local cache over a given HA and/or local coherence of a local memory domain, and/or global coherence across caches and across memory domains). The memory controller 920 may also include additional features to enable operation and coherence of the embedded memory 104.

The home agent 106 also includes I/O interface circuitry 924. The I/O interface circuitry 924 can include pins, pads, connectors, signal lines, traces, or wires, or other hardware to connect the devices, or a combination of these. The I/O interface circuitry 924 can include a hardware interface. In one example, the I/O interfaces circuitry 924 includes at least drivers/transceivers for signal lines. Commonly, wires within an integrated circuit interface couple with a conductive element such as a pad or other conductive interconnect to interface signal lines or traces or other wires between devices. The I/O interface circuitry 924 can include drivers, receivers, transceivers, or termination, or other circuitry or combinations of circuitry to exchange signals on the signal lines between the devices. The exchange of signals includes at least one of transmit or receive. Note that although the I/O interface circuitry 924 is illustrated as a single block, the I/O interfaces represent multiple hardware interfaces for coupling with various signal lines, buses, links, and/or fabrics. For example, the home agent 106 may include multiple hardware interfaces (e.g., an interface between the memory controller 920 and the eDRAM 104, an interface between the memory controller 920 and a chiplet via an interconnect die, etc.

In one example, the home agent 106 may include logic 925 (labeled as interconnect die configuration logic in FIG. 9) to program switches in the interconnect die with which it is coupled. For example, in an IC device with an interconnect die that includes switches for controlling which conductive elements are coupled together, the logic 925 may program the switches based on the desired configuration and number of dies to be stacked over the home agent 106. Programming or configuring switches in the interconnect die may involve, for example, turning on or off particular switches to form conductive pathways between desired components. In one such example, the interconnect die config. logic 925 can enable the same dies (e.g., the same chiplets and/or the same interconnect dies) to be reused to implement different configurations (such as the different configurations illustrated in FIGS. 1A-1D). In one example, the logic 925 may also configure switches in the interconnect die to control which interconnections utilize thicker metal lines to increase the speed of data transfer for those interconnections. For example, to enable fast access between two chiplets over a home agent 106, the logic 925 can program switches in the interconnect die to couple the two chiplets with thicker and more direct metal lines.

In the example illustrated in FIG. 9, the home agent 106 may include error correction circuitry 926. Although illustrated as a separate box, in one example, the error correction circuitry 926 may be a part of the memory controller 920. In one example, the error correction circuitry 926 may detect and/or correct correctable errors in data from cache (e.g., from cache 122-1-122-M of FIG. 8). A home agent 106 may include additional and/or different logic than what is shown in FIG. 9.

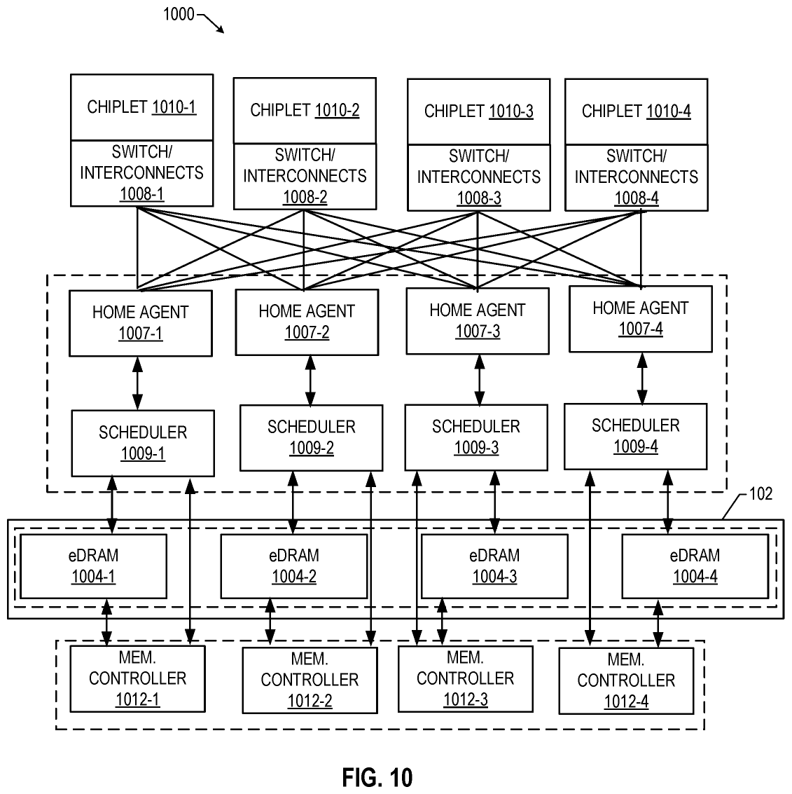

FIG. 10 is a block diagram illustrating interconnections in an example IC device 1000 including an interconnect die between logic dies stacked over a base die with embedded memory. The IC device 1000 includes four chiplets 1010-1, 1010-2, 1010-3, and 1010-4 coupled with four home agents 1007-1, 1007-2, 1007-3, and 1007-4 via respective interconnect dies 1008-1, 1008-2, 1008-3, and 1008-4. The home agents 1007-1, 1007-2, 1007-3, and 1007-4 are shown as being coupled with respective schedulers 1009-1, 1009-2, 1009-3, and 1009-4; however, in other examples, scheduling logic is integrated into the home agents 1007-1, 1007-2, 1007-3, and 1007-4. The schedulers 1009-1, 1009-2, 1009-3, and 1009-4 are coupled with respective memory controllers 1012-1, 1012-2, 1012-3, and 1012-4 and respective eDRAMs 1004-1, 1004-2, 1004-3, and 1004-4. The chiplets 1010-1, 1010-2, 1010-3, and 1010-4 may be examples of chiplets described herein (e.g., the chiplets 110 of FIGS. 1A-1D or the die 310 of FIG. 3), the interconnect dies 1008-1, 1008-2, 1008-3, and 1008-4 may be examples of interconnect dies described herein (e.g., the interconnect die 108-1 of FIGS. 1A-1D or the interconnect die 308 of FIG. 3), the home agent dies 1007-1, 1007-2, 1007-3, and 1007-4 may be examples of home agent dies described herein (e.g., the home agent die 106-1 of FIGS. 1A-1D or the die 106 of FIG. 3), and the eDRAM 1004-1, 1004-2, 1004-3, and 1004-4 may be examples of eDRAM described herein (e.g., the eDRAM 104 of FIG. 1). Different components of the IC device 1000 are shown as disaggregated; however, various components may or may not be implemented in a disaggregated arrangement. For example, the eDRAMs 1004-1, 1004-2, 1004-3, and 1004-4 may represent separate eDRAM arrays, a single eDRAM, or different domains of the same eDRAM. Similarly, although the interconnect dies 1008-1, 1008-2, 1008-3, and 1008-4 are shown as four separate interconnect dies, two or more of the chiplets 1010-1, 1010-2, 1010-3, and 1010-4 may be coupled with the same interconnect die.

In the example illustrated in FIG. 10, each of the chiplets 1010-1, 1010-2, 1010-3, and 1010-4 may have direct access to the embedded memory 1004-1, 1004-2, 1004-3, and 1004-4 (e.g., without necessarily going through a global memory controller, such as a memory controller 112 of FIG. 8) for fast parallel access to the eDRAM 1004-1, 1004-2, 1004-3, and 1004-4. In one such example, the direct access between the chiplets 1010-1, 1010-2, 1010-3, and 1010-4 and the eDRAM 1004-1, 1004-2, 1004-3, and 1004-4 is enabled in part by the interconnect dies 1008-1, 1008-2, 1008-3, and 1008-4 between and hybrid bonded with the chiplets 1010-1, 1010-2, 1010-3, and 1010-4 and the home agent dies 1007-1, 1007-2, 1007-3, and 1007-4, which enable more direct, tighter pitch/high density connectivity and/or a greater number of vertical interconnects (e.g., vias) between the chiplets 1010-1, 1010-2, 1010-3, and 1010-4 and the home agents 1007-1, 1007-2, 1007-3, and 1007-4 and between the home agents 1007-1, 1007-2, 1007-3, and 1007-4 and the eDRAM memory 1004-1, 1004-2, 1004-3, and 1004-4.

As can be seen in FIG. 10, the stacked die configuration with interconnect dies can also enable more direct communication between a chiplet with every other chiplet in the IC device 1000, which may enable fast cache access amongst chiplets. For example, the plurality of chiplets includes a first chiplet 1010-1 that may include a first processor core and a second chiplet 1010-2 that may include a cache. The first chiplet 1010-1 is coupled with the second chiplet 1010-2 via one or more interconnect dies (e.g., the interconnect dies 1008-1, 1008-2 as shown in FIG. 10) and one or more home agent dies (e.g., the home agent dies 1007-1 and 1007-2 as shown in FIG. 10). The first chiplet 1010-1 and the second chiplet 1010-3 may further be coupled via the base die 102. Thus, in one such example, the processor core of the first chiplet 1010-1 may be coupled with the cache of the second chiplet 1010-2 via conductive interconnects in one or more interconnect dies 1008-1, 1008-2, one or more home agent dies 1007-1, 1007-2, and the base die 102.

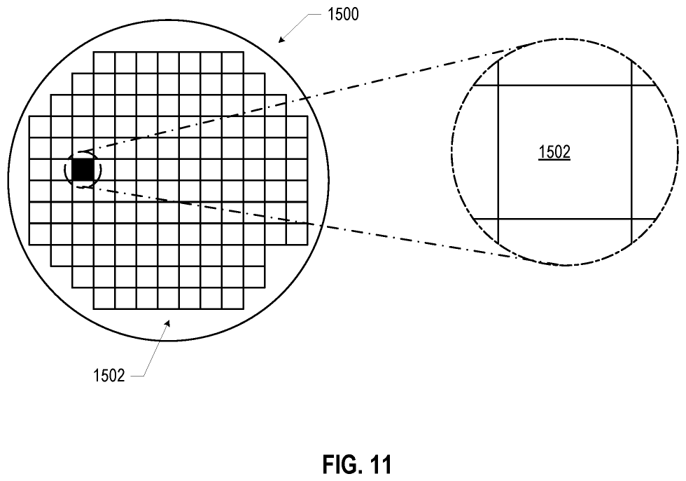

Thus, FIGS. 1A-1D, 2-6, 7A-7C, and 8-10 illustrate various examples of IC devices that include an interconnect die between logic dies stacked over a base die with embedded memory. In accordance with examples, the IC devices described herein may enable fast, high bandwidth, and/or more direct access to embedded memory in a base die than in conventional systems. FIGS. 11-14 illustrate various examples of apparatuses that may include one or more of the IC devices that include an interconnect die between logic dies stacked over a base die with embedded memory disclosed herein.

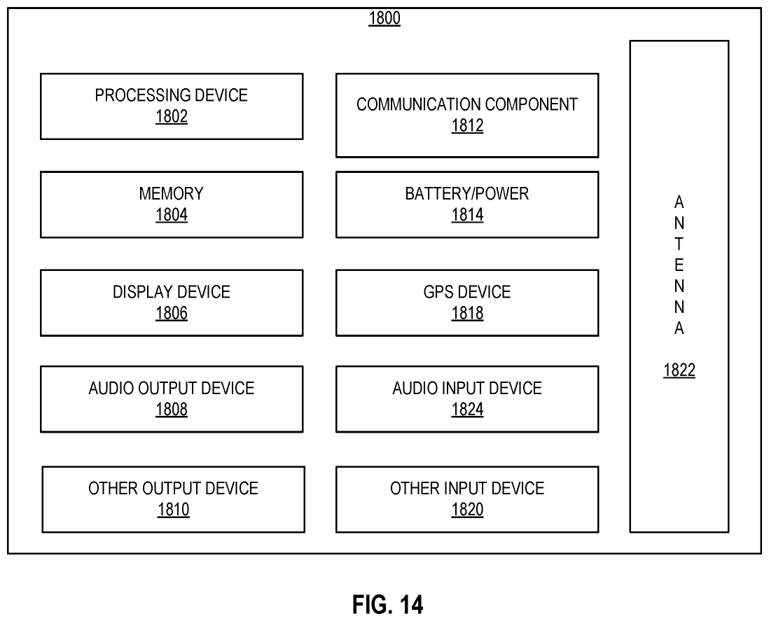

FIG. 11 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. In one example, the dies 1502 may include two or more different dies. In one example, the dies 1502 may be examples of the chiplets 110 of FIGS. 1A-1D or the dies 306, 108, and 310 of FIG. 3. After the fabrication of the semiconductor product is complete, the wafer 1500 may undergo a singulation process in which the dies 1502 are separated from one another to provide discrete “chips” of the semiconductor product. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array.

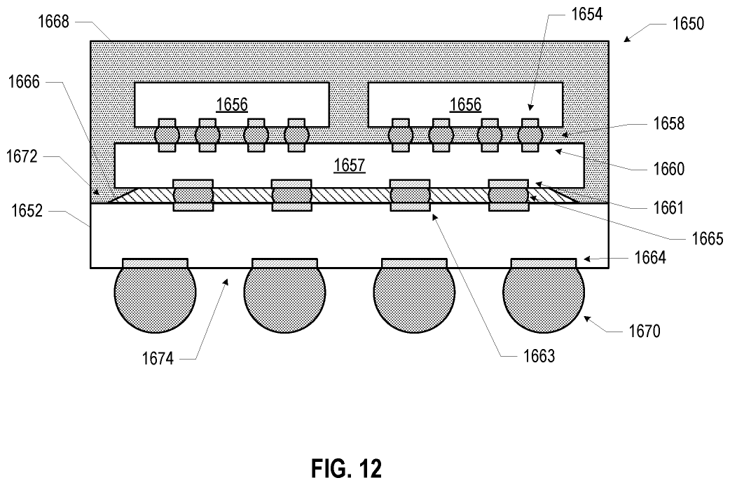

FIG. 12 is a side, cross-sectional view of an example IC package 1650 that may include one or more IC devices that include an interconnect die between logic dies stacked over a base die with embedded memory in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. In one example, the interposer 1657 is an example of a base die, such as the base die 102 of FIGS. 1A-1D, FIG. 3, or FIG. 4. The first-level interconnects 1665 illustrated in FIG. 12 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 12 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket). Although not shown in FIG. 12, the one or more of the dies 1656 may be hybrid bonded to the interposer 1657, such as shown in FIG. 3.

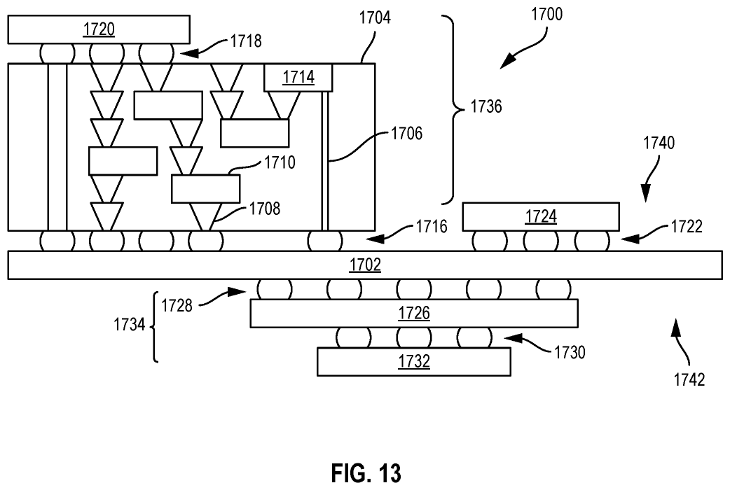

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 12 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 13.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 12 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 12, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 13 is a side, cross-sectional view of an IC device assembly 1700 that may include one or more IC packages or other electronic components (e.g., a die) including one or IC devices that include an interconnect die between logic dies stacked over a base die with embedded memory in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 12 (e.g., may include one or more IC structures in accordance with embodiments described herein).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 11), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 13, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example electrical device 1800 that may include one or more IC devices that include an interconnect die between logic dies stacked over a base die with embedded memory in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 14 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 14, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). The processing device 1802 may be or include a processor core, such as the processor cores 120-1-120-N of FIG. 8. The processing device 1802 may be, or be included in or on, a chiplet, such as the chiplets 110 of FIG. 8. As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM). The memory 1804 may be or include DRAM embedded in an interposer or base die, such as the eDRAM 104 of FIG. 1.

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an integrated circuit (IC) device, including an interposer including embedded memory; a first die (e.g., an HA die) over the interposer, where the first die is hybrid bonded with the interposer and where the first die includes a first device region and first conductive interconnects; a second die (e.g., chiplet) over the first die, where the second die includes a second device region and second conductive interconnects; and a third die (e.g., a switch/interconnect die) between the first die and the second die, where: the third die is hybrid bonded with the first die and the second die, the third die includes a plurality of interconnect layers, where the plurality of interconnect layers includes third conductive interconnects, and the first device region and the second device region are coupled via the third conductive interconnects.

Example 2 provides the IC device of example 1, where: the first die has a first thickness; and the second die has a second thickness; and the third die has a third thickness, where the third thickness is 5-20 times smaller than the first thickness.

Example 3 provides the IC device of any one of examples 1-2, further including a first bonding interface between the first die and the interposer; a second bonding interface between the first die and the third die; and a third bonding interface between the third die and the second die.

Example 4 provides the IC device of example 3, where: the first bonding interface includes a first interface layer; the second bonding interface includes a second interface layer; the third bonding interface includes a third interface layer; and the first interface layer, the second interface layer, and the third interface layer include one or more of silicon, nitrogen, oxygen, and carbon.

Example 5 provides the IC device of any one of examples 3-4, where: the first die (e.g., an HA die) has a first front side and a first back side, where the first device region is closer to the first back side than to the first front side; the second die (e.g., a chiplet) has a second front side and a second back side, where the second device region is closer to the second back side than to the second front side; the second bonding interface is between the first front side and the third die; and the third bonding interface is between the second back side and the third die.

Example 6 provides the IC device of example 5, where: the third die (e.g., a switch die) includes a third device region, a third front side, and a third back side, where the third device region is closer to the third back side than to the third front side; the second bonding interface is between the first front side and the third front side; and the third bonding interface is between the second back side and the third back side.

Example 7 provides the IC device of example 5, where: the third die includes a third device region and one or more backside layers; and the third bonding interface is between the second back side and one or more backside layers of the third die.

Example 8 provides the IC device of any one of examples 1-7, where: the first die includes a first backend via; the second die includes a second backend via; the third die includes a third backend via; and in a cross-section of the IC device in a plane substantially perpendicular to the first device layer, the first backend via and the second backend via have shapes that tapers in a direction towards the interposer, and the third backend via has a shape that tapers in a direction from the third backend via away from the interposer.

Example 9 provides the IC device of example 8, where: the third die further includes a backside via; and in a cross-section of the IC device in a plane substantially perpendicular to the first device layer, the backside via has a shape that tapers in a direction from the backside via towards the interposer.

Example 10 provides the IC device of any one of examples 1-9, where: the second die is one of a plurality of second dies over the third die and bonded with the third die.

Example 11 provides the IC device of example 10, where: the plurality of second dies includes a first compute die and a second compute die; and the first compute die is coupled with the second compute die via the third conductive interconnects of the third die.

Example 12 provides the IC device of example 11, where: the first compute die includes a processor core and memory.

Example 13 provides the IC device of example 11, where: the plurality of second dies includes an SRAM die.

Example 14 provides the IC device of any one of examples 10-12, where: the plurality of second dies includes a memory die.

Example 15 provides the IC device of any one of examples 1-14, where: transistors are absent from the third die.

Example 16 provides the IC device of any one of examples 1-15, where: the third die includes a third device region with a transistor, where the transistor is coupled with the first device region of the first die and the second device region of the second die.

Example 17 provides the IC device of any one of examples 1-16, where: the third die includes six or fewer interconnect layers.

Example 18 provides the IC device of any one of examples 1-17, where: the interposer includes fourth conductive interconnects; the first die is coupled with the embedded memory via the fourth conductive interconnects of the interposer.

Example 19 provides the IC device of any one of examples 1-18, where: the embedded memory includes an array of memory cells, where an individual memory cell of the array includes a thin film transistor.

Example 20 provides the IC device of any one of examples 1-19, where: the first die includes memory control logic and an SRAM array (e.g., tag array).

Example 21 provides an integrated circuit (IC) device, including a first die (e.g., the HA die) over a base die that includes a memory array, where the first die includes memory controller circuitry (e.g., a local memory controller of an HA die); a second die (e.g., a chiplet) over the first die, where the second die includes a processor core; and a third die (e.g., an interconnect die) between the first die and the second die, where the third die includes a conductive interconnect coupled with the memory controller circuitry and the processor core; and a first bonding interface between the third die and the first die, and a second bonding interface between the third die and the second die.

Example 22 provides the IC device of example 21, where: the first bonding interface includes a first bonding layer in contact with the third die and the first die; and the second bonding interface includes a second bonding layer in contact with the third die and the second die.

Example 23 provides the IC device of any one of examples 21-22, further including a third bonding interface between the first die and the base die.

Example 24 provides the IC device of any one of examples 21-23, further including a fourth die over the third die, where: the fourth die includes one or more of a processor core and an SRAM cache, the third die includes a further conductive interconnect coupled with the processor core or the SRAM cache of the fourth die and the memory controller circuitry of the first die, and a further bonding interface is present between the fourth die and the third die.

Example 25 provides the IC device of any one of examples 21-24, where: the third die is a passive die without transistors.

Example 26 provides the IC device of any one of examples 21-24, where: the third die includes a transistor coupled with the conductive interconnect.

Example 27 provides the IC device of any one of examples 21-26, where: the third die is 5-20 times thinner than one or more of the first die and the second die.

Example 28 provides the IC device of any one of examples 21-27, where: the memory array includes backend transistors.

Example 29 provides an integrated circuit (IC) device, including a first IC structure (e.g., a base die) including a memory array and first conductive interconnects; a second IC structure (e.g., a HA die) over the first IC structure and bonded with the first IC structure, where the second die includes a device region and second conductive interconnects; a third IC structure (e.g., an interconnect die) over the second IC structure and bonded with the second IC structure, where the third IC structure includes third conductive interconnects; and a plurality of chiplets over the third IC structure, where: the plurality of chiplets includes a first chiplet that includes a processor core and a second chiplet that includes a cache, the first chiplet and the second chiplet are bonded with the third IC structure, and the processor core is coupled with the cache via the first conductive interconnects, the second conductive interconnects, and the third conductive interconnects.

Example 30 provides the IC device of example 29, where: the third IC structure includes a passive die including six or fewer interconnect layers over a substrate.

Example 31 provides the IC device of any one of examples 29-30, further including a first bonding interface between the first IC structure and the second IC structure; a second bonding interface between the second IC structure and the third IC structure; a third bonding interface between the third IC structure and the first chiplet; and a fourth bonding interface between the third IC structure and the second chiplet.

Example 32 provides the IC device according to any one of examples 1-31, where the IC device includes or is a part of a central processing unit.

Example 33 provides the IC device according to any one of examples 1-32, where the IC device includes or is a part of a memory device.

Example 34 provides the IC device according to any one of examples 1-33, where the IC device includes or is a part of a logic circuit.

Example 35 provides the IC device according to any one of examples 1-34, where the IC device includes or is a part of input/output circuitry.

Example 36 provides the IC device according to any one of examples 1-35, where the IC device includes or is a part of a field programmable gate array transceiver.

Example 37 provides the IC device according to any one of examples 1-36, where the IC device includes or is a part of a field programmable gate array logic.

Example 38 provides the IC device according to any one of examples 1-37, where the IC device includes or is a part of a power delivery circuitry.

Example 39 provides an IC package that includes an IC device according to any one of examples 1-38; and a further IC component, coupled to the IC device.

Example 40 provides the IC package according to example 39, where the further IC component includes a package substrate.

Example 41 provides the IC package according to example 39, where the further IC component includes an interposer.

Example 42 provides the IC package according to example 39, where the further IC component includes a further IC device/die.

Example 43 provides a computing device or system that includes a carrier substrate and an IC device coupled to the carrier substrate, where the IC device is an IC device according to any one of examples 1-38, or the IC device is included in the IC package according to any one of examples 39-42.

Example 44 provides the computing device or system according to example 43, where the computing device is a wearable or handheld computing device.

Example 45 provides the computing device or system according to examples 43 or 44, where the computing device further includes one or more communication chips.

Example 46 provides the computing device according to any one of examples 43-45, where the computing device further includes an antenna.

Example 47 provides the computing device according to any one of examples 43-46, where the carrier substrate is a motherboard.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
an interposer including embedded memory;
a first die over the interposer, wherein the first die is hybrid bonded with the interposer and wherein the first die includes a first device region and first conductive interconnects;
a second die over the first die, wherein the second die includes a second device region and second conductive interconnects; and
a third die between the first die and the second die, wherein:
the third die is hybrid bonded with the first die and the second die, the third die includes a plurality of interconnect layers, wherein the plurality of interconnect layers includes third conductive interconnects, and the first device region and the second device region are coupled via the third conductive interconnects.

2. The IC device of claim 1, wherein:
the first die has a first thickness;
the second die has a second thickness; and
the third die has a third thickness, wherein the third thickness is 5-20 times smaller than the first thickness.

3. The IC device of claim 1, further comprising:
a first bonding interface between the first die and the interposer;
a second bonding interface between the first die and the third die; and
a third bonding interface between the third die and the second die.

4. The IC device of claim 3, wherein:
the first bonding interface includes a first interface layer;
the second bonding interface includes a second interface layer;
the third bonding interface includes a third interface layer; and
the first interface layer, the second interface layer, and the third interface layer include one or more of silicon, nitrogen, oxygen, and carbon.

5. The IC device of claim 3, wherein:
the first die has a first front side and a first back side, wherein the first device region is closer to the first back side than to the first front side;
the second die has a second front side and a second back side, wherein the second device region is closer to the second back side than to the second front side;
the second bonding interface is between the first front side and the third die; and
the third bonding interface is between the second back side and the third die.

6. The IC device of claim 5, wherein:
the third die includes a third device region, a third front side, and a third back side, wherein the third device region is closer to the third back side than to the third front side;
the second bonding interface is between the first front side and the third front side; and
the third bonding interface is between the second back side and the third back side.

7. The IC device of claim 5, wherein:
the third die includes a third device region and one or more backside layers; and
the third bonding interface is between the second back side and one or more backside layers of the third die.

8. The IC device of claim 1, wherein:
the first die includes a first backend via;
the second die includes a second backend via;
the third die includes a third backend via; and
in a cross-section of the IC device in a plane substantially perpendicular to the first device layer, the first backend via and the second backend via have shapes that tapers in a direction towards the interposer, and the third backend via has a shape that tapers in a direction from the third backend via away from the interposer.

9. The IC device of claim 8, wherein:
the third die further includes a backside via; and
in a cross-section of the IC device in a plane substantially perpendicular to the first device layer, the backside via has a shape that tapers in a direction from the backside via towards the interposer.

10. The IC device of claim 1, wherein:
the second die is one of a plurality of second dies over the third die and bonded with the third die.

11. The IC device of claim 10, wherein:
the plurality of second dies includes a first compute die and a second compute die; and
the first compute die is coupled with the second compute die via the third conductive interconnects of the third die.

12. The IC device of claim 11, wherein:
the first compute die includes a processor core and memory.

13. The IC device of claim 11, wherein:
the plurality of second dies includes an SRAM die.

14. The IC device of claim 10, wherein:
the plurality of second dies includes a memory die.

15. The IC device of claim 1, wherein:
transistors are absent from the third die.

16. The IC device of claim 1, wherein:
the third die includes a third device region with a transistor, wherein the transistor is coupled with the first device region of the first die and the second device region of the second die.

17. An integrated circuit (IC) device, comprising:
a first die over a base die that includes a memory array, wherein the first die includes memory controller circuitry;
a second die over the first die, wherein the second die includes a processor core;
a third die between the first die and the second die, wherein the third die includes a conductive interconnect coupled with the memory controller circuitry and the processor core; and
a first bonding interface between the third die and the first die, and a second bonding interface between the third die and the second die.

18. The IC device of claim 17, wherein:
the first bonding interface includes a first bonding layer in contact with the third die and the first die; and
the second bonding interface includes a second bonding layer in contact with the third die and the second die.

19. An integrated circuit (IC) device, comprising:
a first IC structure including a memory array and first conductive interconnects;
a second IC structure over the first IC structure and bonded with the first IC structure, wherein the second IC structure includes a device region and second conductive interconnects;
a third IC structure over the second IC structure and bonded with the second IC structure, wherein the third IC structure includes third conductive interconnects; and
a plurality of chiplets over the third IC structure, wherein:
the plurality of chiplets includes a first chiplet that includes a processor core and a second chiplet that includes a cache, the first chiplet and the second chiplet are bonded with the third IC structure, and the processor core is coupled with the cache via the first conductive interconnects, the second conductive interconnects, and the third conductive interconnects.

20. The IC device of claim 19, wherein:
the third IC structure includes a passive die including six or fewer interconnect layers over a substrate.
